(19) United States
(12) Patent Application Publication
(10) Pub. No.: US 2006/0273380 A1
(43) Pub. Date: Dec. 7, 2006

(54) Source contact and metal scheme for high density trench MOSFET

(75) Inventor: Fwu-Iuan Hshieh, Saratoga, CA (US)

Correspondence Address: Bo-In Lin, 13445 Mandoli Drive, Los Altos Hills, CA, 94022, US

(73) Assignee: M-MOS Sdn.Bhd.

(21) Appl. No.: 11/147,075

(22) Filed: Jun. 6, 2005

(51) Int. Cl. H01L 29/78; H01L 21/336

(52) U.S. Cl. 257/330; 438/270; 438/589; 257/382

(57) ABSTRACT

A trenched metal oxide semiconductor field effect transistor (MOSFET) cell that includes a trenched gate surrounded by a source region encompassed in a body region above a drain region disposed on a bottom surface of a substrate. The MOSFET cell further includes a source-body contact trench opened with sidewalls substantially perpendicular to a top surface into the source and body regions and filled with contact metal plug.

### BACKGROUND OF THE INVENTION

1. Field of the Invention

This invention relates generally to the cell structure and fabrication process of power semiconductor devices. More particularly, this invention relates to a novel and improved cell structure and improved process for fabricating a trenched semiconductor power device with improved source metal contacts.

2. Description of the Prior Art

Conventional technologies of forming aluminum metal contact to the N+ source and P-body in a semiconductor device is encountering a technical difficulty of poor metal coverage and unreliable electrical contact when the cell pitch is shrunken. The technical difficulty is especially pronounced when a metal oxide semiconductor field effect transistor (MOSFET) cell density is increased above 200 million cells per square inch (200M/in²) with the cell pitch reduced to 1.8 um or to even a smaller dimension. The metal contact space to both N+ source and P-body for cell density higher than 200M/in² is less than 1.0 um, resulting in poor metal step coverage and high contact resistance to both N+ and P-body region. The device performance is adversely affected by these poor contacts and the product reliability is also degraded.

Referring to FIG. 1 for a standard conventional MOSFET cell 10 formed in a semiconductor substrate 15 with a drain region of a first conductivity type, e.g., an N+ substrate, formed at a bottom surface. The trenched MOSFET cell is formed on top of an epitaxial layer 20 of a first conductivity type, e.g., N− epi-layer that having a lower dopant concentration than the substrate. A body region 25 of a second conductivity type, e.g., a P-body region 120, is formed in the epi-layer 20 and the body region 25 encompasses a source region 30 of the first conductivity type, e.g., N+ source region 30. Each MOSFET cell further includes a N+ doped polysilicon gate 35 disposed in a trench insulated from the surrounding epi-layer 20 with a gate oxide layer 40. The MOSFET cell is insulated from the top by an NSG and BPSG layer 45-1 and 45-2 with a source contact opening to allow a source contact metal layer 50 comprises titanium or Ti/TiN layer 50 to contact the source regions 30. A single metal contact layer 60 overlaying on top to contact the N+ and P-well horizontally. The prior art MOSFET cell as shown in FIG. 1 encounters two fundamental issues due to the cell pitch shrinkage. One is the reduced contact area to both N+ source and P-body, resulting in high contact resistance. Another is poor metal step coverage due to high aspect ratio of contact height and open dimension.

In U.S. Pat. No. 6,638,826, Zeng et al. disclose a MOS power device as shown in FIG. 2 that includes V-groove trench contact to dispose single layer of metal to electrically contact the source vertically. The contact CD (Critical Dimension) can be shrunk significantly without increasing contact resistance, however, the formation of the V-groove contact is not easily controlled as result of wet chemical etch. Moreover, the contact CD is limited by an aluminum metal step coverage due to small contact.

Therefore, there is still a need in the art of the semiconductor device fabrication, particularly for trenched power MOSFET design and fabrication, to provide a novel transistor structure and fabrication process that would resolve these difficulties and design limitations.

### SUMMARY OF THE PRESENT INVENTION

It is therefore an object of the present invention to provide new and improved processes to form a reliable source contact metal layer such that the above-discussed technical difficulties may be resolved.

Specifically, it is an object of the present invention to provide a new and improved cell configuration and fabrication process to form a source metal contact by opening a source-body contact trench by applying an oxide etch followed by a silicon etch. The source-body contact trench then filled with a metal plug to assure reliable source contact is established.

Another aspect of the present invention is to reduce the source and body resistance by forming a thin low-resistance layer with greater contact area to a top thick metal. The thin low-resistance layer forms a good contact to the source-body metal contact plug from the top opening of the source-body contact trench.

Another aspect of the present invention is to connect the front thick metal layer with either bonding wire or cooper plate to the electrodes of a lead-frame. The cooper plate connections provide reduced resistance and improved thermal dissipation performance.

Another aspect of the present invention is to further reduce the source and body resistance by applying a differential etch process to form the source-body contact trench with a wider top opening. A thin low-resistance layer is then formed on top of the MOSFET cell with wider opening area to contact the metal contact plug deposited into the source-body contact trench. The thin low resistance layer has a greater contact area to a top thick metal. The thin low-resistance layer further forms an improved contact to the source-body metal contact plug with wider contact area from the top opening of the source-body contact trench.

Briefly, in a preferred embodiment, the present invention discloses a trenched metal oxide semiconductor field effect transistor (MOSFET) cell that includes a trenched gate surrounded by a source region encompassed in a body region above a drain region disposed on a bottom surface of a substrate. The MOSFET cell further includes a source-body contact trench opened with sidewalls substantially perpendicular to a top surface into the source and body regions and filled with contact metal plug. In a preferred embodiment, the contact metal plug further comprising a Ti/TiN barrier layer surrounding a tungsten core as a source-body contact metal. In another preferred embodiment, the MOSFET cell further includes an insulation layer covering a top surface over the MOSFET cell wherein the source body contact trench is opened through the insulation layer. And, the MOSFET cell further includes a thin resistance-reduction conductive layer disposed on a top surface covering the insulation layer and contacting the contact metal plug whereby the resistance-reduction conductive layer having a greater area than a top surface of the contact metal plug for reducing a source-body resistance. In another preferred embodiment, the contact metal plug filled in the source body contact trench comprising a substantially cylindrical shaped plug. In another preferred embodiment, the MOSFET cell further includes a thick front metal layer disposed on top of the resistance-reduction layer for providing a contact layer for a wire or wireless bonding package. In an alternate preferred embodiment, the source-body contact trench having stepwise sidewalls and said contact metal plug filled in said source-body contact trench comprising a substantially cup shaped plug having a wider top contact area.

This invention further discloses a method for manufacturing a trenched metal oxide semiconductor field effect transistor (MOSFET) cell. The method includes a step of forming said MOSFET cell with a trenched gate surrounded by a source region encompassed in a body region above a drain region disposed on a bottom surface of a substrate. The method further includes a step of covering the MOSFET cell with an insulation layer and applying a contact mask for opening a source-body contact trench with sidewalls substantially perpendicular to a top surface of the insulation layer into the source and body regions. The method further includes a step of filling the source-body contact trench with contact metal plug. In a preferred embodiment, the step of covering the MSOFET cell with an insulation layer further comprising a step of depositing two different oxide layers on top of the MOSFET cell and applying a differential oxide etch to form a source-body contact trench having a step-wise sidewall with a wider top opening.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

FIG. 1 is a side cross-sectional view of a conventional MOSFET device.

FIG. 2 is a cross sectional view of a trenched MOSFET device with V-Groove trench contact disclosed by a patented disclosure.

FIG. 3 is a cross sectional view of a MOSFET device of this invention with an improved source-plug contact.

FIG. 4 is a cross sectional view of another MOSFET device of this invention with an improved source-plug contact filled in a contact trench opening with stepwise sidewalls.

FIGS. 5A to 5J are a serial of side cross sectional views for showing the processing steps for fabricating a semiconductor trench as shown in FIG. 3.

FIG. 5F′ is a side cross sectional view for illustrating a differential etch process to form a source-body contact trench with a step-wise sidewall for depositing a champagne-cup shaped source-body contact therein.

FIGS. 6A and 6B are top views of two kinds of bonding connections according two alternate embodiments of this invention.

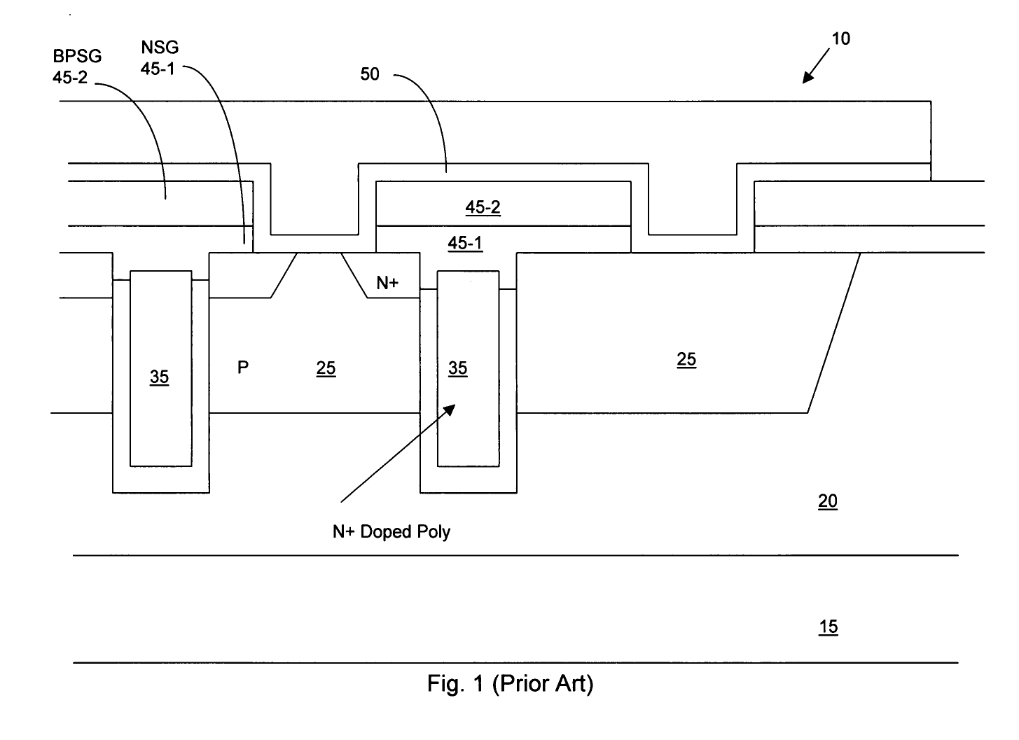

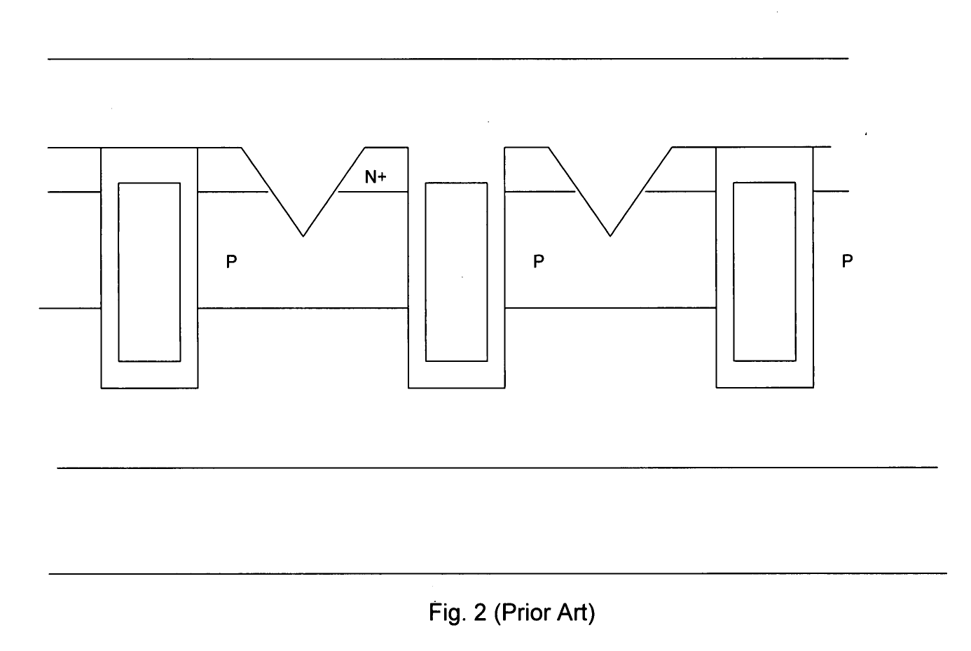

### DETAILED DESCRIPTION OF THE PREFERRED EMBODIMENT

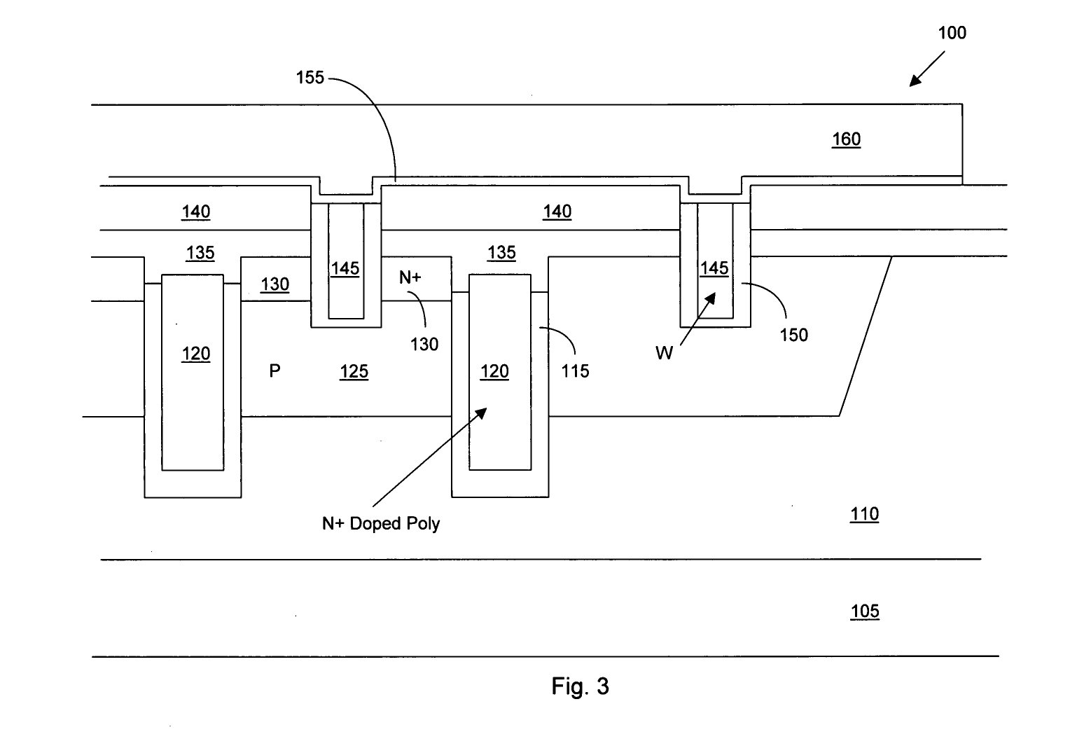

Please refer to FIG. 3 for a first preferred embodiment of this invention where a metal oxide semiconductor field effect transistor (MOSFET) device 100 is supported on a substrate 105 formed with an epitaxial layer 110. The MOSFET device 100 includes a trenched gate 120 disposed in a trench with a gate insulation layer 115 formed over the walls of the trench. A body region 125 that is doped with a dopant of second conductivity type, e.g., P-type dopant, extends between the trenched gates 120. The P-body regions 125 encompassing a source region 130 doped with the dopant of first conductivity, e.g., N+ dopant. The source regions 130 are formed near the top surface of the epitaxial layer surrounding the trenched gates 125. The top surface of the semiconductor substrate extending over the top of the trenched gate, the P body regions 125 and the source regions 130 are covered with a NSG and a BPSG protective layers 135 and 140 respectively.

For the purpose of improving the source contact to the source regions 130, a plurality of trenched source contact filled with a tungsten plug 145 surrounded by a barrier layer Ti/TiN 150. The contact trenches are opened through the NSG and BPSG protective layers 135 and 140 to contact the source regions 130 and the P-body 125. Then a conductive layer 155 is formed over the top surface to contact the trenched source contact 145 and 150. A top contact layer 160 is then formed on top of the source contact layer 155. The top contact layer 160 is formed with aluminum, aluminum-cooper, AlCuSi, or Ni/Ag, Al/NiAu, AlCu/NiAu or AlCuSi/NiAu as a wire-bonding layer. The conductive layer 155 sandwiched between the top wire-bonding layer 160 and the top of the trenched source-plug contact is formed to reduce the resistance by providing greater area of electrical contact.

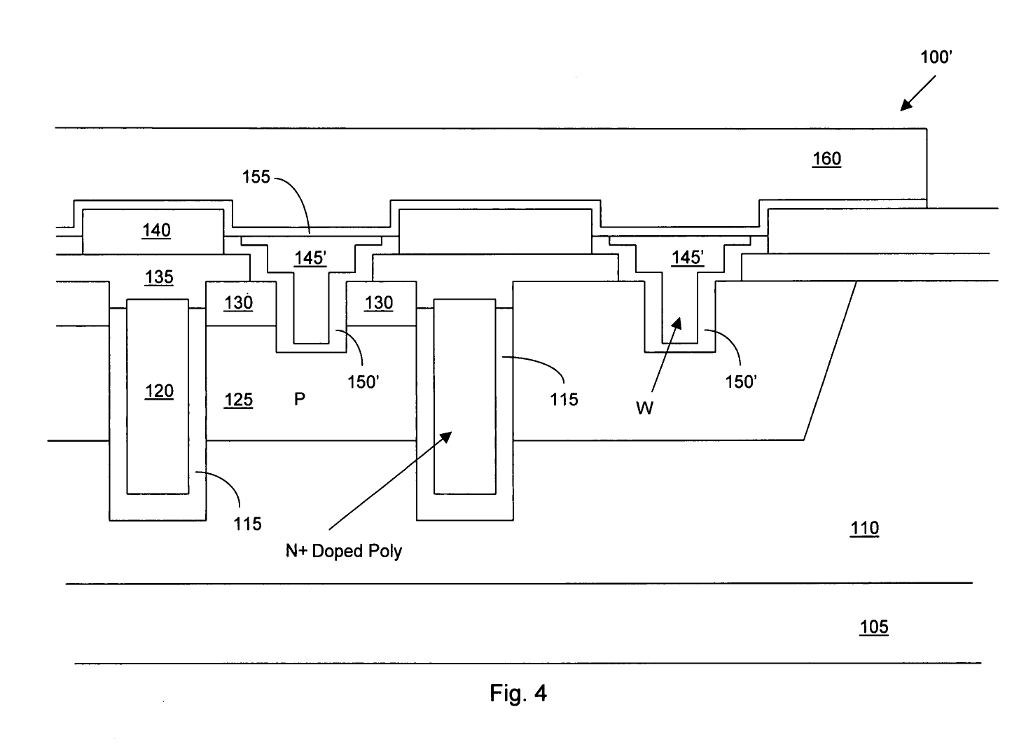

FIG. 4 show another MOSFET device 100′ with similar device configuration as that shown in FIG. 3. The MOSFET device 100′ also has a source contact plug 145′ composed of tungsten surrounded by conductive barrier layer Ti/TiN 150′. The only difference is the shape of the trench for disposing the source contact plug 145′ is formed with a stepwise sidewall thus the 145′ plug has a shape like that of champagne cup. The source-body contact trench with stepwise sidewall provides additional advantage. With a wider top opening, a broader contact area is provided and the contact resistance between the source-body contact plug and the top thick metal is further reduced.

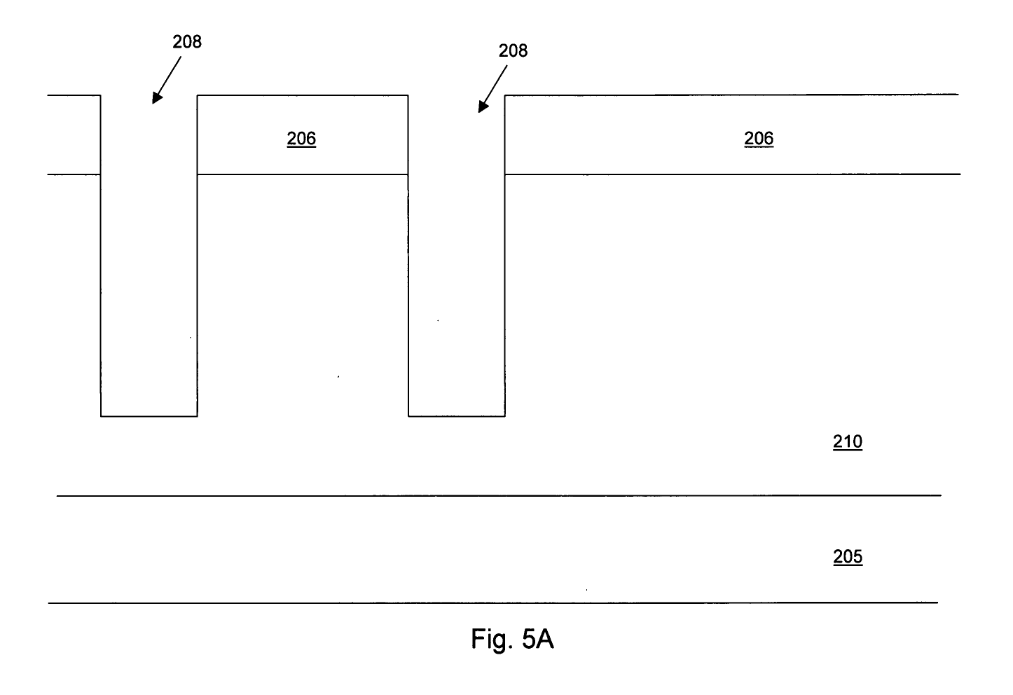

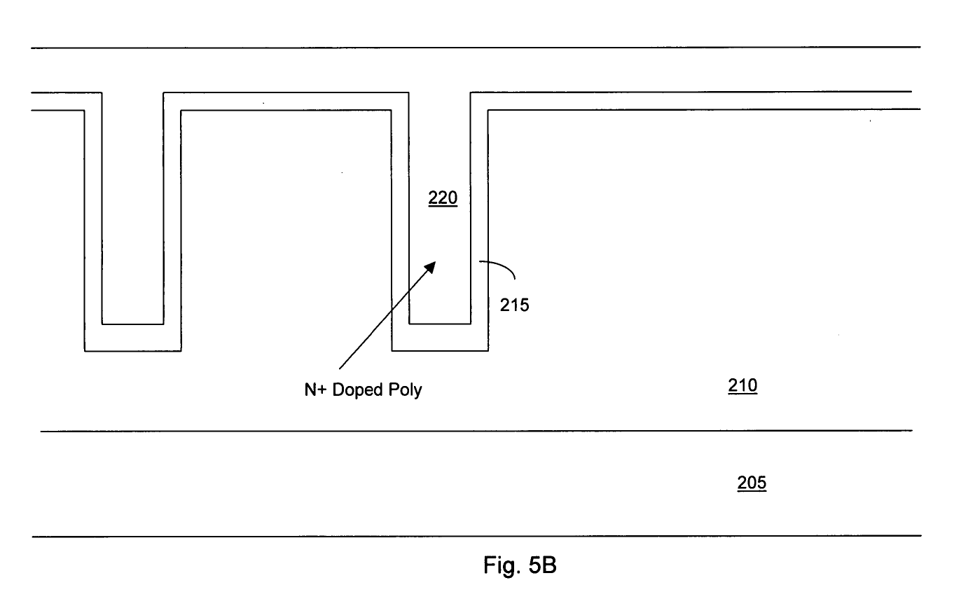

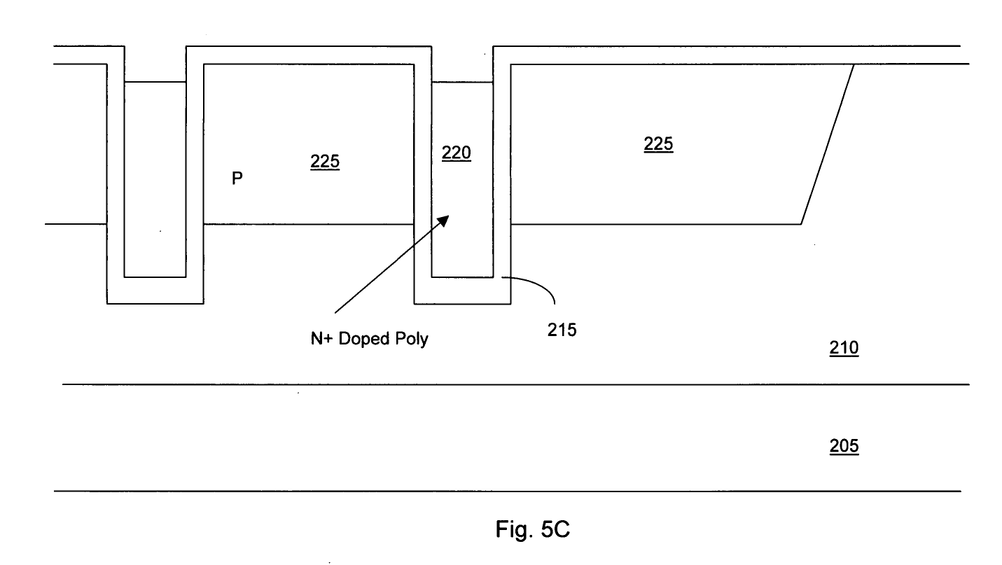

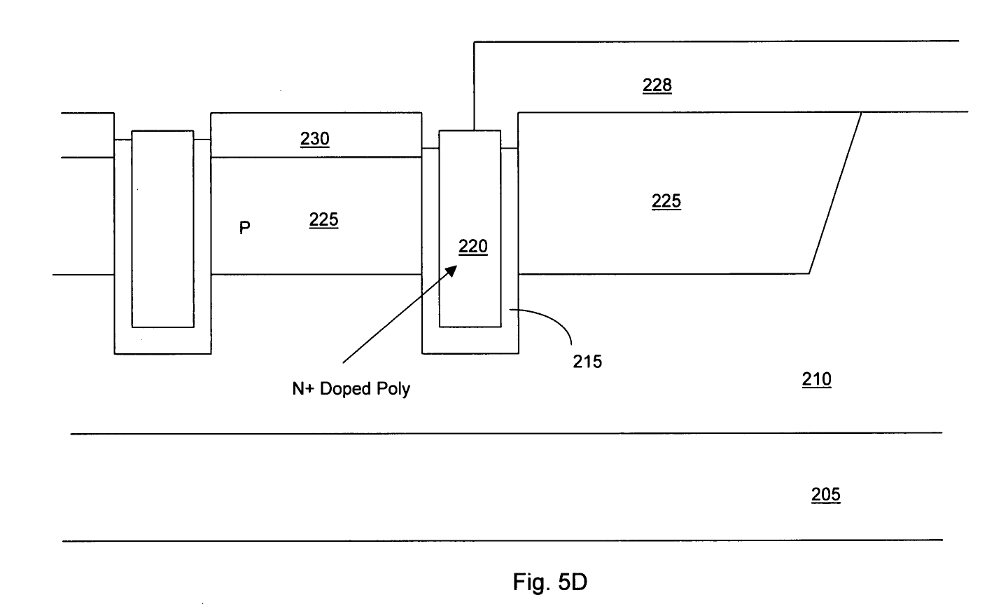

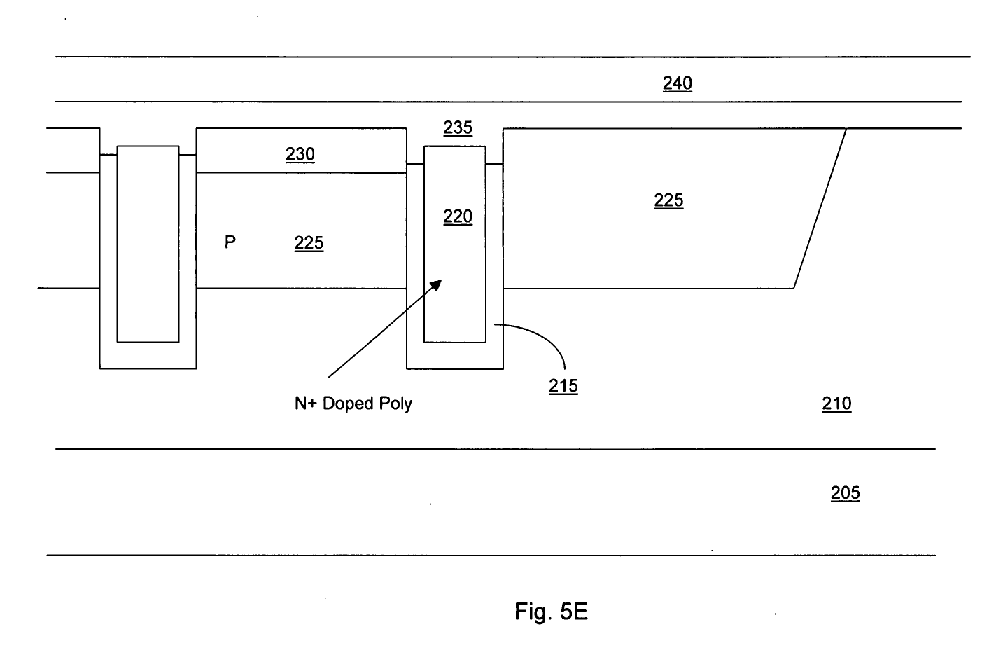

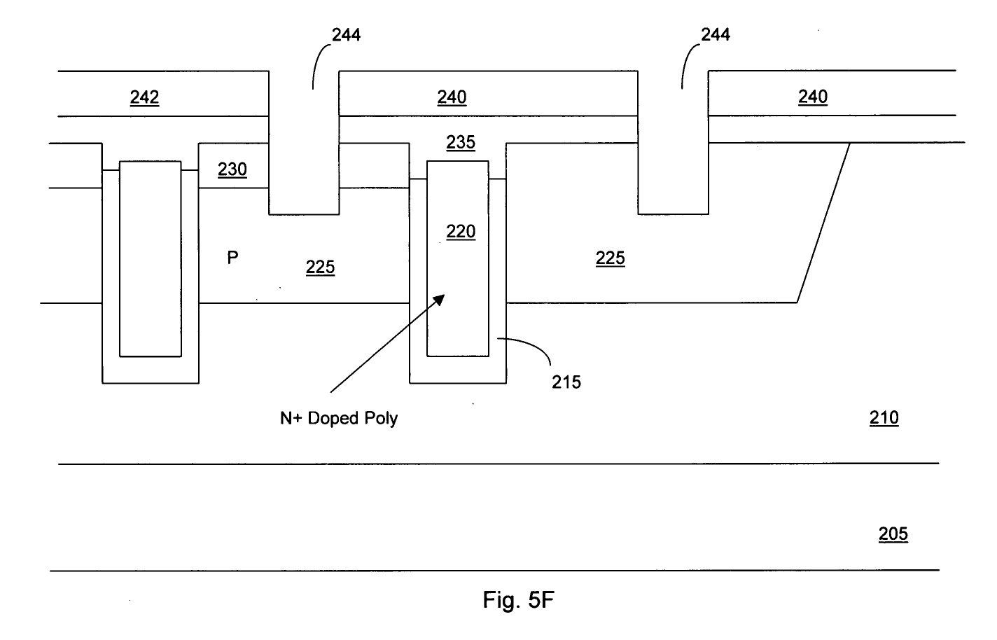

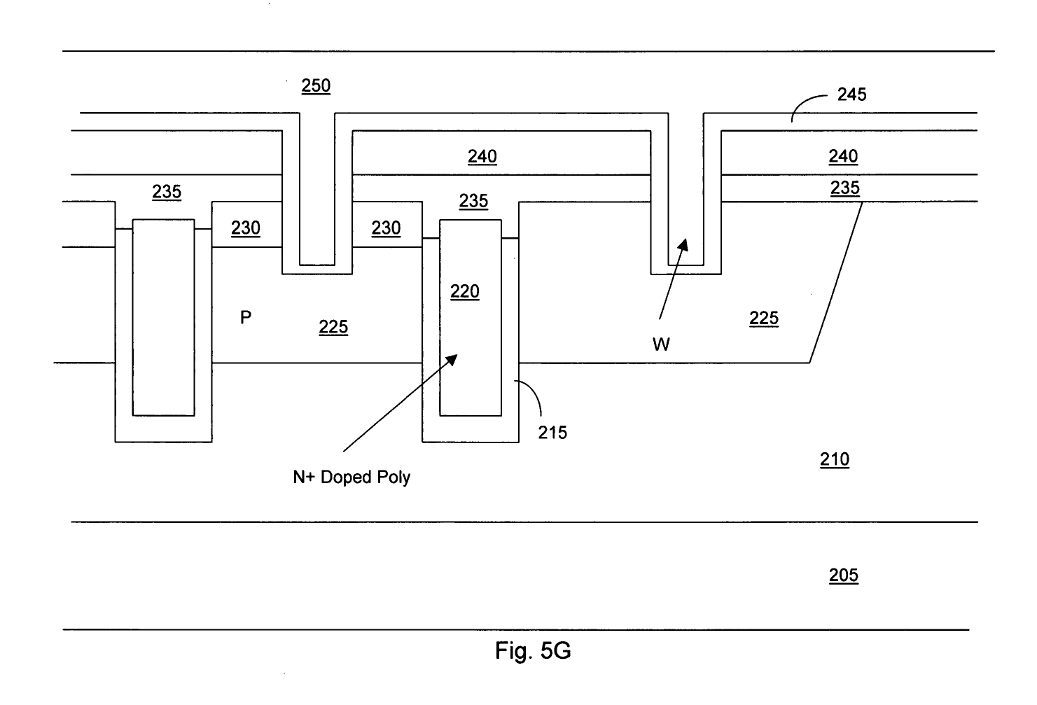

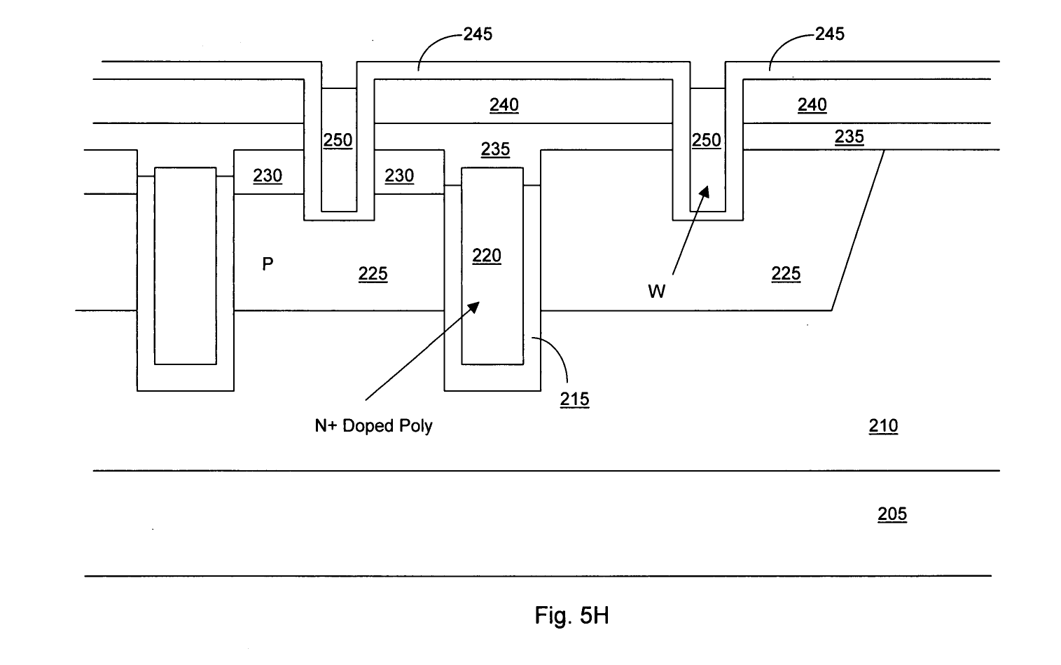

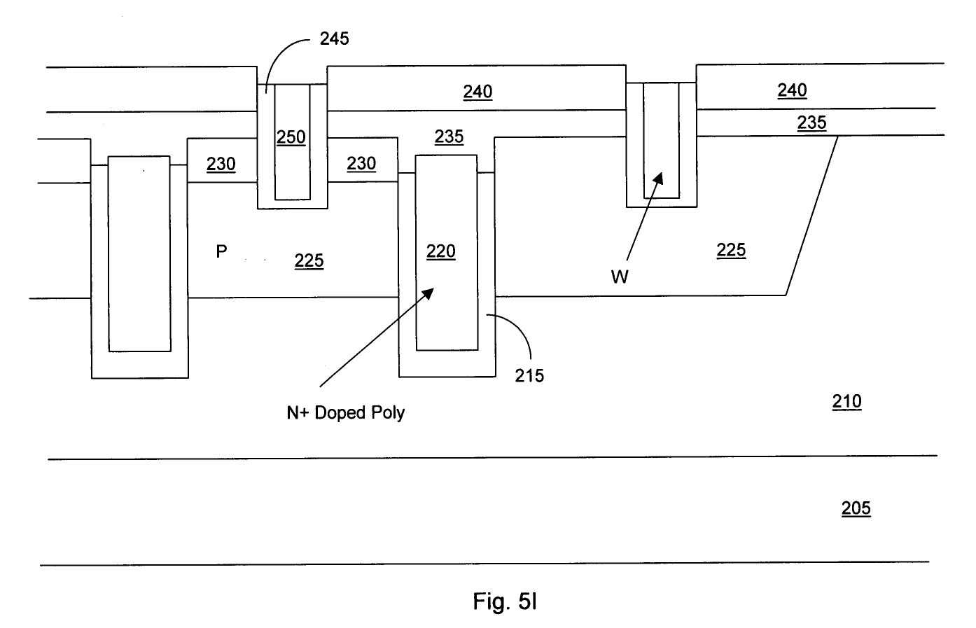

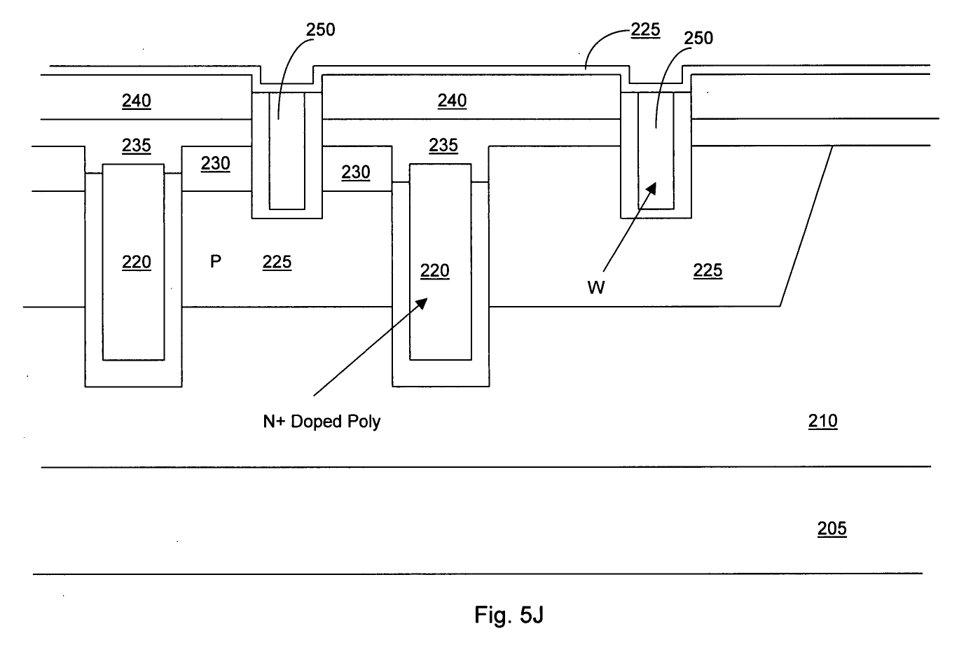

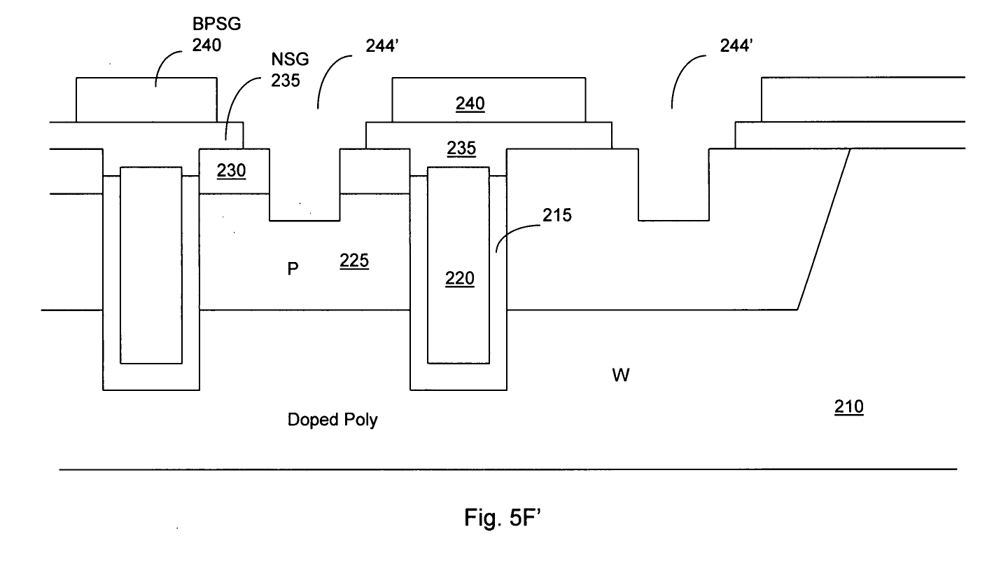

Referring to FIGS. 5A to 5J for a serial of side cross sectional views to illustrate the fabrication steps of a MOSFET device as that shown in FIG. 3. In FIG. 5A, a photoresist 206 is applied to open a plurality of trenches 208 in an epitaxial layer 210 supported on a substrate 205. In FIG. 5B, an oxidation process is performed to form an oxide layer 215 covering the trench walls. The trench is oxidized with a sacrificial oxide to remove the plasma damaged silicon layer during the process of opening the trench. Then a polysilicon layer 220 is deposited to fill the trench and covering the top surface and then doped with an N+ dopant. In FIG. 5C, the polysilicon layer 220 is etched back followed by a P-body implant with a P-type dopant. Then an elevated temperature is applied to diffuse the P-body 225 into the epitaxial layer 210. In FIG. 5D, a source mask 228 is applied followed by an source implant with a N-type dopant. Then an elevated temperature is applied to diffusion the source regions 230. In FIG. 5E, a non-doped oxide (NSG) layer 235 and a BPSG layer 240 are deposited on the top surface. In FIG. 5F, a contact mask 242 is applied to carry out a contact etch to open the contact opening 244 by applying an oxide etch through the BPSG and NSG layers followed by a silicon etch to open the contact openings 242 further deeper into the source regions 230 and the body regions 225. The MOSFET device thus includes a source-body contact trench 244 that has an oxide trench formed by first applying an oxide-etch through the oxide layers, e.g., the BPSG and NSG layers. The source-body contact trench 244 further includes a silicon trench formed by applying a silicon-etch following the oxide-etch. The oxide etch and silicon etch may be a dry oxide and silicon etch whereby a critical dimension (CD) of the source-body contact trench is better controlled. In FIG. 5G, a Ti/TiN layer 245 is deposited onto the top layer followed by forming a tungsten layer 250 on the top surface that fill in the contact opening to function as a source and body contact plug. In FIG. 5H, a tungsten etch is carried out to etch back the tungsten layer 250. In FIG. 5I, a Ti/TiN etch is carried out to etch back the Ti/TiN layer 245. In FIG. 5J, a low resistance metal layer 255 is deposited over the top surface. The low resistance metal layer may be composed of Ti or Ti/TiN to assure good electric contact is established.

Referring further to FIG. 5F′ for an additional differential etching process after the completion of the step shown in FIG. 5F. In FIG. 5F′, a differential etch of NSG and BPSG is performed by using a dilute HF (10:1). A stepwise sidewall trench 244′ is formed because of the different etch rates between NSG layer 235 and BPSG layer 240. The etch rate of NSG is 50 A/min if the dilute HF is 100:1 HF, and 300 A for BPSG. For the purpose of fabricating a MOSFET device as that shown in FIG. 4 with stepwise source-body contact trench with a champagne-cup shaped trench plug, the above-described processing steps as that shown in FIGS. 5G to 5J are followed to complete the fabrication processes.

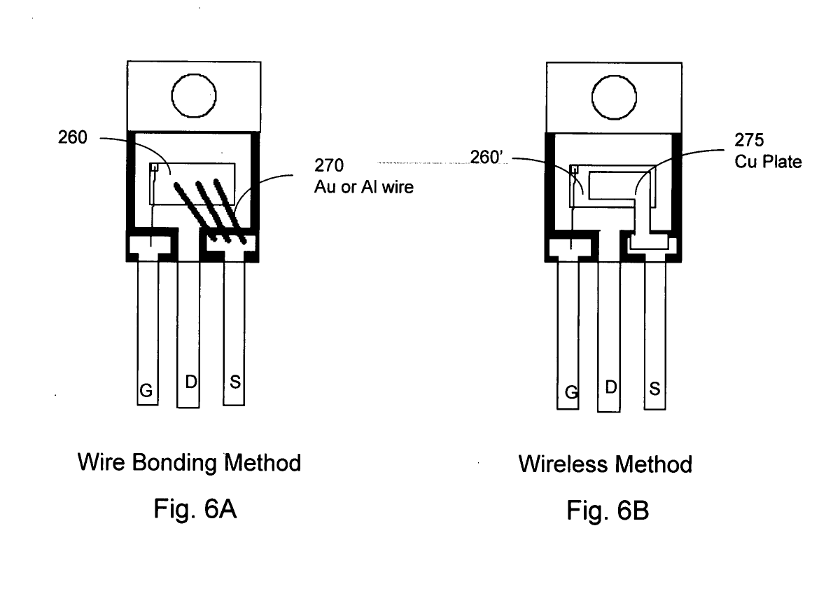

By further depositing a top contact layer 260, as that shown in FIGS. 6A and 6B, over the low resistance metal layer 255, e.g., a top contact layer 160 shown in FIG. 3 completes the manufacture of the device. The top metal 260 can be Al, AlCu or AlCuSi for wire-bonding such as Au wire or Al wire 270 as shown in FIG. 6A while Ni/Ag, Al/NiAu, or AlCu/NiAu or AlCuSi/NiAu top metal contact layer 260′ for wireless solder bonding using Cu Plate 275 as shown in FIG. 6B connected to a source electrode S for on-resistance reduction and improved thermal characteristics.

Although the present invention has been described in terms of the presently preferred embodiment, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

I claim:

1. A trenched metal oxide semiconductor field effect transistor (MOSFET) cell comprising a trenched gate surrounded by a source region encompassed in a body region above a drain region disposed on a bottom surface of a substrate, wherein said MOSFET cell further comprising:
a source-body contact trench opened with sidewalls substantially perpendicular to a top surface into said source and body regions and filled with contact metal plug.

2. The MOSFET cell of claim 1 wherein:
the contact metal plug further comprising a Ti/TiN barrier layer surrounding a tungsten core as a source-body contact metal.

3. The MOSFET cell of claim 1 further comprising:
an insulation layer covering a top surface over said MOSFET cell wherein said source body contact trench is opened through said insulation layer; and
a thin resistance-reduction conductive layer disposed on a top surface covering said insulation layer and contacting said contact metal plug whereby said resistance-reduction conductive layer having a greater area than a top surface of said contact metal plug for reducing a source-body resistance.

4. The MOSFET cell of claim 1 wherein:
said contact metal plug filled in said source body contact trench comprising a substantially cylindrical shaped plug.

5. The MOSFET cell of claim 3 further comprising:
a thick front metal layer disposed on top of said resistance-reduction layer for providing a contact layer for a wire or wireless bonding package.

6. The MOSFET cell of claim 1 further comprising:
the source body contact trench further comprising an oxide trench formed by an oxide-etch through an oxide layer covering a top surface said MOSFET device.

7. The MOSFET cell of claim 1 further comprising:
the source body contact trench further comprising a silicon trench formed by a silicon-etch after an oxide-etch for extending said source-body contract trench into a silicon substrate.

8. The MOSFET cell of claim 1 further comprising:
the source body contact trench further comprising a trench opened by a dry oxide and silicon etch whereby a critical dimension (CD) of said source-body contact trench is better controlled.

9. The MOSFET cell of claim 1 further comprising:
the source body contact trench further comprising a trench opened by a dry oxide and silicon etch followed by a wet oxide layer to form irregular shaped trench sidewalls.

10. The MOSFET cell of claim 1 wherein:
the contact metal plug further contacts said source region on trench sidewalls of said source body contact trench and contact metal plug contacts said body region through a bottom surface of said source body contact trench.

11. The MOSFET cell of claim 3 wherein:
said thin resistance-reduction conductive layer comprising a titanium (Ti) layer.

12. The MOSFET cell of claim 3 wherein:
said thin resistance-reduction conductive layer comprising a titanium nitride (TiN) layer.

13. The MOSFET cell of claim 5 wherein:
said front thick metal layer comprising an aluminum layer.

14. The MOSFET cell of claim 5 wherein:
said front thick metal layer comprising an AlCu layer.

15. The MOSFET cell of claim 5 wherein:
said front thick metal layer comprising an AlCuSi layer.

16. The MOSFET cell of claim 5 wherein:
said front thick metal layer comprising an Al/NiAu layer.

17. The MOSFET cell of claim 5 wherein:
said front thick metal layer comprising an AlCu/NiAu layer.

18. The MOSFET cell of claim 5 wherein:
said front thick metal layer comprising an AlCuSi/NiAu layer.

19. The MOSFET cell of claim 5 wherein:
said front thick metal layer comprising an NiAg layer.

20. The MOSFET cell of claim 5 wherein:
said front thick metal layer comprising an NiAu layer.

21. The MOSFET cell of claim 1 wherein:
said MOSFET cell further comprising a N-channel MOSFET cell.

22. The MOSFET cell of claim 1 wherein:
said MOSFET cell further comprising a P-channel MOSFET cell.

23. The MOSFET cell of claim 1 wherein:
said source-body contact trench having stepwise sidewalls and said contact metal plug filled in said source-body contact trench comprising a substantially cup shaped plug having a wider top contact area.

24. The MOSFET cell of claim 5 further comprising:
aluminum wires for connecting said thick front metal layer to a lead frame.

25. The MOSFET cell of claim 5 further comprising:
gold wires for connecting said thick front metal layer to a lead frame.

26. The MOSFET cell of claim 5 further comprising:
a cooper plate for connecting said thick front metal layer to a lead frame.

27. A method for manufacturing a trenched metal oxide semiconductor field effect transistor (MOSFET) cell comprising a step of forming said MOSFET cell with a trenched gate surrounded by a source region encompassed in a body region above a drain region disposed on a bottom surface of a substrate, the method further comprising:
covering said MOSFET cell with an insulation layer and applying a contact mask for opening a source-body contact trench with sidewalls substantially perpendicular to a top surface of said insulation layer into said source and body regions.

28. The method of claim 27 further comprising:
filling said source-body contact trench with contact metal plug.

29. The method of claim 27 wherein:
said step of covering said MSOFET cell with an insulation layer further comprising a step of depositing two different oxide layers on top of said MOSFET cell and applying a differential oxide etch to form a source-body contact trench having a step-wise sidewall with a wider top opening.
